(19) United States
(12) Patent Application Publication
(10) Pub. No.: US 2011/0127077 A1
(43) Pub. Date: Jun. 2, 2011

(54) BLOCK COPOLYMERIZED POLYIMIDE INK COMPOSITION FOR PRINTING

(76) Inventors: Maw Soe WIN, Yokohama-shi (JP); Toshiyuki Goshima, Yokohama-shi (JP); Eika Kyo, Yokohama-shi (JP); Shintaro Nakajima, Yokohama-shi (JP); Noriki Hayashi, Osaka-shi (JP); Tohru Kashiwagi, Osaka-shi (JP); Kenji Miyazaki, Osaka-shi (JP); Katsuya Yamada, Kouga-shi (JP); Naoyuki Yamabayashi, Kouga-shi (JP); Shoji Nakagama, Kouga-shi (JP); Hiroshi Okuyama, Kouga-shi (JP); Fumio Kasabo, Kouga-shi (JP); Ippei Tanaka, Kouga-shi (JP)

(21) Appl. No.: 13/025,581

(22) Filed: Feb. 11, 2011

Related U.S. Application Data
(63) Continuation of application No. 12/470,399, filed on May 21, 2009, now abandoned.
Application No. 12/470,399 is a continuation of application No. 11/597,694, filed on Jan. 25, 2008, now abandoned.

(30) Foreign Application Priority Data
May 27, 2004 (JP) 2004-157228

(51) Int. Cl. H05K 1/00; C08K 5/101; C08K 5/3492; C08K 5/5399; C08K 5/3475; C08L 79/08; B05D 5/00

(52) U.S. Cl. 174/258; 524/287; 524/101; 524/115; 524/88; 427/256

(57) ABSTRACT

The object is to provide a polyimide ink composition having good printing properties and good continuous priming properties, which composition can be dried at a low temperature of not higher than 220° C., and which composition gives a coating film, after being dried, having excellent dimensional stability, heat resistance, low modulus of elasticity, flexibility, resistance to warping, chemical resistance, adhesiveness with substrates, and plating resistance. This object is accomplished by a polyimide ink composition for printing, comprising a mixed solvent containing an benzoic acid ester solvent and a glyme solvent, and a polyimide soluble in the mixed solvent; wherein the polyimide is obtained by polycondensing a polyimide oligomer with a tetracarboxylic dianhydride component(s) and/or a diamine component(s) having no siloxane bond in molecular skeleton thereof, the polyimide oligomer being prepared by polycondensing a tetracarboxylic dianhydride component(s) and a diamine component(s) having siloxane bonds in molecular skeleton thereof in the presence of a base catalyst(s), or a mixed catalyst including a lactone(s) and/or an acidic compound(s) and a base(s); the content of the diamine component(s) having siloxane bonds based on the total diamine components being 15 to 85% by weight.

### TECHNICAL FIELD

The present invention relates to a polyimide ink composition for printing. More particularly, the present invention relates to a block-polyimide copolymer ink composition having good continuous printing property, which composition can be dried at a low temperature of not higher than 220° C., and which composition gives a coating film, after being dried, having excellent dimensional stability, heat resistance, flexibility, adhesiveness with substrates, and plating resistance, and with which a micropatterned film can be formed in a batch.

### BACKGROUND ART

Polyimides are now being more and more used as the protective films of flexible printing boards and semiconductor wafers because they are excellent in heat-resistance. Methods for forming a polyimide protective film include methods wherein cover lay films which are polyimide films are laminated; methods wherein a polyimide ink is printed; and methods wherein a polyimide for photoresist is coated and patterned by exposure to UV light.

The methods using cover lay films require not only manpower in the operation to laminate the punched cover lay films, but also require a lengthy treatment under high temperature and high pressure using a large and expensive hot plate press in the heat press step. Therefore, the methods have problems in that they are inefficient, and the dimensional stability is low, so that the yield of the products is low and the production cost is high. Further, since epoxy and acrylic resins are mainly used as the adhesives, if a solder not containing lead is used for the packaging, the heat-resistance is not sufficient.

As the methods for printing a polyimide ink, methods are known wherein a partially imidized polyamic acid solution having a high concentration is coated on a substrate through a template and the coated film is completely imidized on the substrate (Patent Literature 1). The coated film must be treated at a high temperature of 240° C. to 350° C. for attaining imidization. In this imidization reaction, the large shrinkage of the polyimide resin to be formed is a big problem on the processability, and, especially, it is difficult to form the polyimide film as a micropatterned protective layer in semiconductor wafers or the like. Further, since the solvent used in the ink is highly hygroscopic NMP, DMF or the like, the methods have problems in that polyamic acid is likely to precipitate due to the moisture absorption of the varnish, that the polyimide is whitened during printing, and that clogging of the screen occurs, so that continuous printing is difficult.

As the methods for patterning a coated polyimide film, methods so called photosensitive polyimide methods are known wherein a polyamic acid precursor is coated on a substrate, the irradiated portions (positive type) or non-irradiated portions (negative type) are dissolved by exposure to UV light and development, and the remaining polyamic acid is imidized. However, any of these methods includes exposure to UV light, and several steps are required for the patterning treatment.

To overcome these problems, a method has been proposed in Patent Literature 2 and so on wherein a coating film is formed by the screen printing method using a varnish of a polyamic acid or a polyimide. However, as the polyamic acid varnish or the polyimide varnish used in this method, only those having a low resin concentration of about ten and several % can be used due to the limitation from the viscosity suitable for use, so that it is difficult to form a thick film. Further, there are problems in that if the ink is coated on a circuit board having a metal such as aluminum and cured at a high temperature, curling occurs during cooling, and that the polyamic acid reacts with the wiring layers.

The first mode of the varnish used in the above-described polyimide layer is in the form of polyamic acid, so that an imidizing (ring closure by heat) step is required. In the imidization reaction, the large shrinkage of the polyimide resin to be formed is a big problem on the processability, and particularly, it is difficult to form the film as the protective layer having a fine pattern on a semiconductor wafer or the like. Further, since the polyamic acid varnish is slowly hydrolyzed (depolymerization reaction) at normal temperature due to the moisture absorption, there are a number of problems in that the shelf stability of the varnish is poor, and so on. The second mode is that the cyclized polyimide after completion of imidization is used. Since this polyimide has a low solubility, the concentration of the solids cannot be made high, so that it is difficult to prepare a varnish. Further, because of the low solubility, there are problems in that the amount of the filler component to be added is limited so that the control of the viscosity is difficult, and that thixotropic character is hardly obtained.

As a resin composition for printing which is excellent in heat-resistance and with which the curling after curing is prevented, for example, a polyimide ink is known which comprises an ester-terminated oligomer and an amine-terminated oligomer, disclosed in Patent Literature 3. However, such an ink must be heat-treated at a temperature not lower than 250° C. for imidization, and the shrinkage of the formed polyimide resin is large, which is a big problem on processability. Further, in cases where copper foil is used as the circuit material, a reaction between the carboxyl groups and the wiring material occurs, so that there are problems in that the wiring material is oxidized, and that the adhesion of the ink to the circuit board is drastically decreased.

A technique wherein a polyimide siloxane comprising diaminosiloxane as the diamine component is used as a precursor in order to carry out curing at a low temperature is disclosed in, for example, Patent Literature 4 and Patent Literature 5. However, although with these polyimide siloxanes, the resin concentration can be increased by increasing the amount of the copolymerized diaminosiloxane, the solder dip resistance is inversely decreased so that there is a problem in reliability. There is also a problem in that in cases where circuits are multilaminated using adhesive sheets such as prepregs and bonding sheets, the each circuit being coated with a protective film prepared by coating the above-described polysiloxane precursor on a circuit board and by subsequent imidization thereof, the adhesion between the protective film and the adhesive sheet is very weak.

Further, Patent Literature 6 and Patent Literature 7 disclose a solution composition containing a soluble polyimide siloxane and an epoxy resin. This solution composition has a problem in that its chemical resistance is poor because the polyimide is solvent-soluble. Moreover, there are practical problems in that the composition is easy to dry during screen printing, so that clogging of screen mesh occurs and it is very difficult to form patterns. Further, Patent Literature 8 discloses a composition of a soluble polyimide comprising 10 mol % of a silicone diamine. Although the coating film after drying prepared from the composition has excellent chemical resistance, heat resistance, and adhesiveness with substrates and adhesive sheets, improvements in flexibility and warping characteristics are demanded. On the other hand, Patent Literature 9 discloses in Examples 1 and 2 thereof a soluble polyimide composition using 33 mol % of silicone diamine, and in Example 4, a soluble polyimide composition using 50 mol % of silicone diamine. Although these compositions are excellent in low warping characteristics, chemical resistance, heat resistance, flexibility, and adhesiveness with substrates and adhesive sheets, they are poor in ease of handling in printing if the composition is used as an ink for printing.
Patent Literature 1: Japanese Translated PCT Patent Application Laid-open No. 10-502869
Patent Literature 2: JP 62-242393 A
Patent Literature 3: JP 2-145664 A
Patent Literature 4: JP 57-143328 A
Patent Literature 5: JP 58-13631 A
Patent Literature 6: JP 4-298093 A
Patent Literature 7: JP 6-157875 A
Patent Literature 8: JP 2003-113338 A
Patent Literature 9: JP 2003-119285 A

### DISCLOSURE OF THE INVENTION

### Problems which the Invention Tries to Solve

An object of the present invention is to provide a polyimide ink composition for printing, having good printing property and good continuous printing property, which composition can be dried at a low temperature of not higher than 220° C., and which composition gives a coating film, after being dried, having excellent dimensional stability, heat resistance, low modulus of elasticity, flexibility, resistance to warping, chemical resistance, adhesiveness with substrates, and plating resistance. Another object of the present invention is to provide a polyimide ink composition for printing comprising the resin at a high concentration, with which micropatterning with a size of not more than 200 μm can be formed in a batch. Still another object of the present invention is to provide a polyimide ink composition for printing having excellent continuous printing property.

### Means for Solving the Problems

To attain the above-described objects, the present inventors intensively studied to discover that a composition comprising a mixed solvent containing an benzoic acid ester solvent and a glyme solvent, and a polyimide having siloxane bonds, which polyimide is obtained by a specific production process, attains the object, thereby completing the present invention.

That is, the present invention provides a polyimide ink composition for printing, comprising a mixed solvent containing an benzoic acid ester solvent and a glyme solvent, and a polyimide soluble in said mixed solvent, wherein said polyimide is obtained by polycondensing a polyimide oligomer with a tetracarboxylic dianhydride component(s) and/or a diamine component(s) having no siloxane bond in molecular skeleton thereof, said polyimide oligomer being prepared by polycondensing a tetracarboxylic dianhydride component(s) and a diamine component(s) having siloxane bonds in molecular skeleton thereof in the presence of a base catalyst(s), or a mixed catalyst including a lactone(s) and/or an acidic compound(s) and a base(s); the content of said diamine component(s) having siloxane bonds based on the total diamine components being 15 to 85% by weight, preferably 35 to 80% by weight.

### Effects of the Invention

With the polyimide ink composition for printing according to the present invention, even when printing is performed in an environment at room temperature and at a humidity of not more than 50%, there is no blur on the surface of the substrate, and a pattern of through holes with a size of not larger than 200 μm can be continuously print-coated 100 times or more. Further, the solid content of the polyimide ink composition for printing is as much as 30 to 50%. Still further, since the high temperature treatment (240 to 350° C.) is not necessary, drying can be carried out at a low temperature of 220° C. or lower, so that the dimensional change before and after the drying is small. Since a tetracarboxylic dianhydride component(s) is(are) already contained in the ink composition, no free carboxyl groups are contained in the ink composition. Therefore, the reaction between the circuit material and the carboxyl groups does not occur, so that oxidation of the circuit material does not occur and strong adhesion can be obtained. The resulting protective film or adhesive layer has a low modulus of elasticity and high elongation, and excels in dimensional stability, mechanical characteristics, flexibility, heat resistance, and adhesiveness with substrates. Further, by blending as a coloring agent a halogen-free phthalocyanine which is an organic pigment in an amount of 2 to 10% based on solid content of the polyimide resin, the inconvenience in the inspection process or the like, which inconvenience is due to the transparency of the resin, can be eliminated. Still further, by blending an insulating filler, hydrated metal compound (magnesium hydroxide, aluminum hydroxide, calcium aluminate, calcium carbonate), aluminum oxide, titanium dioxide, phosphorus compound (red phosphorus, condensed phosphoric acid ester, phosphazene compound), resin-coated organic filler or resin filler in an amount of 5 to 10 parts by weight based on the resin solid content, fire retardancy can be promoted without deteriorating the characteristics intrinsic to the resin, and without deteriorating the processability, and a uniform thick film which is free from voids and bubbles, in which the contents of dusts and ionic impurities are small, and which excels in reliability, can be formed in a batch with a high productivity.

### BEST MODE FOR CARRYING OUT THE INVENTION

The present invention will now be described in detail.

The polyimide used in the present invention is obtained by a two-step reaction. The polyimide is obtained by first polycondensing a tetracarboxylic dianhydride component(s) and a diamine component(s) having siloxane bonds in the molecular skeleton thereof to obtain an oligomer; and then polycondensing the thus obtained oligomer with a tetracarboxylic dianhydride component(s) and/or a diamine component(s) which does not have a siloxane bond in the molecular skeleton thereof to extend the chain. By preventing random copolymerization caused by the ester exchange reaction between the auric acid molecules so as to prepare a block copolymer, the solubility of the polyimide is increased, adhesiveness is imparted, and electric and mechanical properties can be improved when compared with the method wherein not less than 3 components are mixed and a random copolymer is prepared.

The diamine having the siloxane bonds in the molecular skeleton thereof used in the first step may be any diamine as long as an imide can be formed with the tetracarboxylic dianhydride, and examples thereof include those having the structures represented by the following [Chem 1] or [Chem 2]:

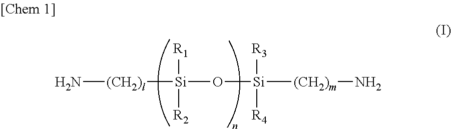

(wherein in Formula (I), R₁, R₂, R₃ and R₄ each independently represents alkyl, cycloalkyl, phenyl, or phenyl substituted with 1 to 3 alkyl or alkoxyl groups; l and m each independently represents an integer of 1 to 4; and n represents an integer of 3 to 30).

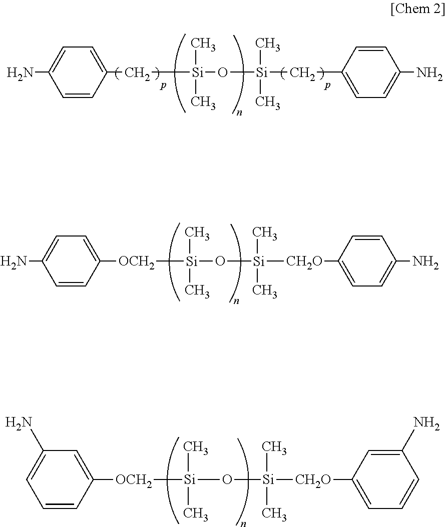

(wherein p represents an integer of 0 to 4; and n represents an integer of 1 to 30, preferably 1 to 20).

These diaminosiloxanes may be used individually, or mixtures of two or more of these can be used in combination. As the above-described siloxane-containing diamine, commercially available products may be used, and, for example, the products commercially available from Shin-Etsu Chemical, Dow Corning Toray and Chisso may be used as they are. Specific examples include KF-8010 produced by Shin-Etsu Chemical (amino equivalent of about 450, in Formula (I), R₁, R₂, R₃ and R₄ are methyl groups; and l and m are 3), X-22-161A (amino equivalent of about 840, in Formula (I), R₁, R₂, R₃ and R₄ are methyl groups; and l and m are 3) and the like.

On the other hand, as the tetracarboxylic dianhydride component(s) used in the first step, an aromatic tetracarboxylic dianhydride(s) is(are) usually used in view of the heat resistance of the polyimide and the compatibility with the siloxane bond-containing diamine(s). Examples thereof include pyromellitic dianhydride, 3,3′,4,4′-biphenyltetracarboxylic dianhydride, bis(3,4-dicarboxyphenyl)ether dianhydride, 3,3′,4,4′-benzophenonetetracarboxylic dianhydride, bicyclo[2,2,2-]octo-7-ene-2,3,5,6-tetracarboxylic dianhydride, 2,2-bis(3,4-dicarboxyphenyl)hexafluoropropane dianhydride, 3,3′,4,4′-biphenylsulfonetetracarboxylic dianhydride and the like. Among these, especially preferred are 3,3′,4,4′-biphenyltetracarboxylic dianhydride, bis(3,4-dicarboxyphenyl)ether dianhydride, 3,3′,4,4′-benzophenonetetracarboxylic dianhydride, and 3,3′,4,4′-biphenylsulfonetetracarboxylic dianhydride in view of the heat resistance of the polyimide, adhesiveness with conductor lines, compatibility with siloxane bond-containing diamine(s) and polymerization rate. These exemplified tetracarboxylic dianhydrides may be used individually, or two or more of these may be used in combination.

In the reaction in the first step, a diamine(s) other than the diamine(s) having siloxane bonds may be included. As such a diamine(s), an aromatic diamine(s) is(are) usually used in view of the heat resistance of the polyimide, adhesiveness with the conductor lines and increase in polymerization degree. Examples of such aromatic diamines include 9,9′-bis(4-aminophenyl)fluorene, m-phenylenediamine, p-phenylenediamine, 2,4-diaminotoluene, 4,4′-diamino-3,3′-dimethyl-1,1′-biphenyl, 4,4′-diamino-3,3′-dihydroxy-1,1′-biphenyl, 3,4′-diaminodiphenyl ether, 4,4′-diaminodiphenyl ether, 3,3′-diaminodiphenylsulfone, 4,4′-diaminodiphenylsulfone, 4,4′-diaminodiphenyl sulfide, 2,2-bis(4-aminophenyl)propane, 2,2-bis(4-aminophenyl)hexafluoropropane, 1,3-bis(3-aminophenoxy)benzene, 1,3-bis(4-aminophenoxy)benzene, 1,4-bis(4-aminophenoxy)benzene, 4,4′-bis(4-aminophenoxy)biphenyl, 2,2-bis[4-(4-aminophenoxy)phenyl]propane, 2,2-bis[4-(4-aminophenoxy)phenyl]hexafluoropropane, bis[4-(3-aminophenoxy)phenyl]sulfone, bis[4-(4-aminophenoxy)phenyl]sulfone, 2,6-diaminopyridine, 2,6-diamino-4-methylpyridine, α,α-bis(4-aminophenyl)-1,3-diisopropylbenzene, α,α-bis(4-aminophenyl)-1,4-diisopropylbenzene, 3,5-diaminobenzoic acid, 3,3′-dicarboxy-4,4′-diaminodiphenylmethane, and the like.

In the total diamine components including those used in the second step, the percentage of the above-described siloxane-containing diamine(s) used in the first step is 15 to 85% by weight, more preferably 35 to 80% by weight. In cases where the content of the siloxane bond-containing diamine units is less than 15% by weight, the elongation of the coating film of the polyimide ink for screen printing is poor, and sufficient flexibility is unlikely to be obtained. Further, warping of the substrate, flexibility and decrease in adhesiveness are likely to occur, which are not preferred. In cases where the content of the siloxane bond-containing diamine units is more than 85% by weight, heat resistance tends to be deteriorated, which is not preferred. The molar ratio of the diamine(s) to the tetracarboxylic dianhydride(s) in the first step is 0.5 to 2.0, and the molar ratio of the total diamines to the total tetracarboxylic dianhydrides is 0.95 to 1.05, preferably 0.98 to 1.02.

As the reaction catalyst, a one-component base catalyst or a mixed catalyst including a lactone(s) and/or an acidic compound(s) is used. Examples of the one-component base catalyst include tertiary amines such as triethylamine and tributylamine; pyridine derivatives such as pyridine, 2-picoline and 2,3-lutidine; 1,4-dimethylpiperazine; N-methylmorpholine and the like. Examples of the mixed catalyst include the mixtures of lactones such as β-butyrolactone and γ-butyrolactone, or acidic compounds such as crotonic acid and oxalic acid, and the above-described basic compounds. The mixing ratio of the acid to base in the acid-base catalyst is 1:1 to 1:5 (molar equivalent), preferably 1:1 to 1:2. In the case of a binary catalyst containing a lactone, the catalyst exhibits catalytic activity as a double salt of acid-base in the presence of water, and after the water is removed from the reaction system after dehydration and imidization, it loses the catalytic activity. The amount of the one-component or the mixed catalyst is 1/100 to ⅕ by mole, preferably 1/50 to 1/10 by mole based on the total tetracarboxylic dianhydrides (including that used in the second step, if any).

As the solvent used in the polymerization reaction, an organic solvent is used. As the organic solvent, a benzoic acid ester solvent(s) and a glyme solvent(s) are preferably used, and the solvent is preferably used as the solvent of the ink composition of the present invention as it is. In view of the drying and clogging of the screen, using a solvent having a vapor pressure at room temperature of not higher than 3 mmHg, more preferably not higher than 1 mmHg, is preferred. Examples of the benzoic acid esters include methyl benzoate, ethyl benzoate, butyl benzoate and the like. Examples of the glyme solvent include triglyme, tetraglyme and the like. To remove the water generated by dehydration and imidization, it is preferred to use a solvent which can be distilled off together with water by azeotropic distillation. Examples of such a solvent are aromatic compounds including alkylbenzenes such as benzene, toluene and xylene; and alkoxybenzenes such as methoxybenzene.

As for the reaction conditions in the first step, the temperature is 140° C. to 180° C., and the reaction time is, although not restricted, usually about 0.5 to 3 hours. The generated water is continuously removed from the system by azeotropic distillation.

When the amount of the generated water reached the theoretical value and water is no longer released to the outside of the system, the reaction mixture is cooled and a tetracarboxylic dianhydride component(s) and/or a diamine component(s) which has(have) no siloxane bond in the molecular skeleton thereof is(are) added to carry out the second step. As the tetracarboxylic dianhydride(s) and the diamine(s) having no siloxane bond, those exemplified above can be used here too. These may be the same or different from those used in the first step. As will be concretely described in Examples below, the tetracarboxylic dianhydride(s), diamine compound(s), and the solvent(s) used in the second step in the prescribed amounts are added, and are allowed to react at 140° C. to 180° C. as in the first step. The generated water is continuously removed from the system by azeotropic distillation. When water is no longer generated, the water is completely distilled off. If water is not completely distilled off at this time, it evaporates during printing and causes change in viscosity, contamination of the environment atmosphere and the like, which are not preferred. Although the reaction time is not restricted and is usually about 3 to 8 hours, since polymerization reaction can be monitored by measuring viscosity and/or by GPC measurements, the reaction is usually continued until a prescribed viscosity and molecular weight are attained. The weight average molecular weight of the polyamide is preferably 30,000 to 200,000, more preferably 30,000 to 120,000. An acid anhydride(s) such as phthalic anhydride or an aromatic amine(s) such as aniline may be added as a terminator.

A general production of such solvent-soluble block polyimide compounds is described in U.S. Pat. No. 5,502,143.

Solvent-soluble copolymerized polyimides can be obtained as described above. The solids concentration at this time is preferably 10 to 50% by weight, more preferably 40 to 45% by weight.

The characteristics of the thus obtained polyimides are now described.

### 1) Thermal Properties

Glass Transition Temperature: 100-280° C. (TG-TDA method)

Temperature at Which Thermal Decomposition Begins: 400-550° C. (TG-TDA method)

### 2) Electric Properties

Volume Resistivity: not less than 10¹⁵ ohms (JIS-C6471 7.1)

Dielectric Constant: 2.5-2.9 (JIS-C6471 7.5)

### 3) Mechanical Properties

Tensile Strength: 10-100 N/mm² (JIS-C2330)

Tensile Elongation: 50-500% (JIS-C2330)

Tensile Modulus of Elasticity: 80-1000 N/mm² (JIS-C2330)

### 4) Chemical Properties

Water Absorption: 0.01-1%

Solder Dip Resistance: not shorter than 60 seconds at 260° C. (JIS-C6471 9.3)

Alkali Resistance The weight loss after being immersed in 5% sodium hydroxide solution for 30 minutes is not more than 1%.

The obtained polyimide copolymer constitutes the ink composition for printing according to the present invention as it is without desolvation, or after adding a necessary solvent(s), additive(s) and the like.

Although the polyimide ink composition for printing according to the present invention has features that run and blur are small when printed, and the stickiness to the screen is small, to give better thixotropic character, a known additive(s) or thixotropic agent(s) may be added. As the filler, insulating inorganic fillers, resin-coated inorganic fillers and resin fillers may be used. Examples of the insulating inorganic fillers include Aerosil, silica (average particle size: 0.001-0.2 μm), hydrated metal compounds (magnesium hydroxide, aluminum hydroxide, calcium aluminate, calcium carbonate), aluminum oxide, titanium dioxide and phosphorus compounds (red phosphorus, condensed phosphoric acid esters, phosphazene compounds). Examples of the resin-coated inorganic fillers include PMMA/polyethylene, silica/polyethylene and the like. Examples of the resin fillers include particulate epoxy resins, melamine polyphosphate, melem, melamine cyanurate, maleimide resins, polyurethane resins, polyimides, polyamides, triazine compounds and the like, having an average particle size of 0.05 μm to 100 μm. The filler is preferably particles having an average particle size of 0.001 μm to 10 μm. The amount of the filler is preferably 5 to 20 parts by weight with respect to 95 to 80 parts by weight of polyimide. As the thixotropic agent, anhydrous silica having silanol groups on the surface thereof in the form of fine powder (average particle size: 1-50 μm) may be exemplified. The amount of the thixotropic agent is preferably 5 to 30 parts by weight with respect to 95 to 70 parts by weight of the polyimide.

Further, an additive(s) such as known antifoaming agent(s) and/or leveling agent(s) may be added. As the leveling agent, it is preferred to add a surfactant component(s) to a concentration of about 100 ppm to about 2% by weight. By this, foaming is suppressed, and the coated film can be made flat. The surfactant is preferably a nonionic surfactant which does not contain ionic impurities. Examples of suitable surfactant include “FC-430” of 3M, “BYK-051” of BYK Chemi, Y-5187, A-1310, SS-2801-2805 of Nippon Unicar. Examples of antifoaming agent include “BYK-A501” of BYK Chemi and “DC-1400” of Dow Corning; and examples of silicone antifoaming agent include SAG-30, FZ-328, FZ-2191 and FZ-5609 of Nippon Unicar; and KS-613 produced by Shin-Etsu Chemical. Further, to inspect the displacement, dust, blur, penetration and the like, a halogen-free phthalocyanine blue which is an organic pigment and which has a high insulation reliability may be added. The amount to be added is preferably 1 to 20 parts by weight, more preferably 2 to 5 parts by weight with respect to 100 parts by weight of the polyimide solid content.

The polyimide ink composition according to the present invention has a good shelf stability as a polyimide solution because the imidization reaction has already been carried out. The composition may be printed on the surfaces of flexible circuit boards and semiconductor wafers by the known screen printing, ink jet printing method or precision dispensing method so as to form films. Since the solid content of the polyimide ink composition according to the present invention can be as high as 40 to 50% by weight, thick films can be formed. Further, since the composition is free from precipitation by moisture absorption and substantially free from clogging in screen printing, continuous printing property is good. Since the imidization reaction has already been carried out, imidization reaction is not necessary after the printing, so that polyimide films can be formed by merely drying to remove the solvent. Removal of the solvent may be carried out in an oven or on a hot plate, at 30° C. to 250° C. depending on the coating thickness, and the treatment may be carried out at a constant temperature throughout the entire treatment or the temperature may be gradually raised. In the treatment for removing the solvent, the maximum temperature is within the range from 90° C. to 220° C., and the treatment is preferably carried out for 5 to 10 minutes in the air or under an inert gas atmosphere such as nitrogen.

### EXAMPLES

The process for producing the polyimide solution used in the present invention and the characteristics thereof will now be described concretely by way of Examples thereof. Since polyimides with various characteristics can be obtained by the combinations of the acid dianhydrides and diamines, the present invention is not restricted to these Examples.

### Synthesis Example 1

To a 3-liter three-necked separable flask to which a stainless steel anchor agitator is attached, a condenser comprising a trap for separation of water and a cooling tube having balls, is attached. To the flask, 882.67 g (3000 mmol) of 3,3′,4,4′-biphenyltetracarboxylic dianhydride (BPDA), 1876.00 g (2000 mmol) of diaminosiloxane compound BY16-853U (amino equivalent: 469) produced by Dow Corning Toray, 30.03 g (300 mmol) of γ-valerolactone, 47.46 g (600 mmol) of pyridine, 1200 g of triglyme, 1200 g of ethyl benzoate and 400 g of toluene are fed. After stirring the mixture at room temperature under a nitrogen atmosphere at 180 rpm for 30 minutes, the temperature was raised to 180° C. and the mixture was stirred for 1 hour. During the reaction, toluene-water azeotrope was removed.

After cooling the mixture to room temperature, 146.17 g (500 mmol) of 1,3-bis(3-aminophenoxy)benzene (APB), 146.17 g (500 mmol) of m-bis(4-aminophenoxy)benzene and 598 g of triglyme were fed, and 598 g of ethyl benzoate and 200 g of toluene were added, followed by allowing the mixture to react at 180° C. for 5 hours with stirring at 180 rpm. By removing the refluxed material from the system, a polyimide solution having a concentration of 45% was obtained. The molecular weight of the thus obtained polyimide was measured by gel permeation chromatography (produced by Tosoh). As a result, the number average molecular weight (Mn) was 19,000, weight average molecular weight (Mw) was 38,000, Z average molecular weight (Mz) was 51,000, and Mw/Mn=1.9, the molecular weights being in terms of polystyrene. The polyimide was poured into methanol and powdered, and subjected to thermal analysis. The glass transition temperature (Tg) was 127.5° C., and the temperature at which decomposition begins was 410.1° C.

### Synthesis Example 2

To a 2-liter three-necked separable flask to which a stainless steel anchor agitator is attached, a condenser comprising a trap for separation of water and a cooling tube having balls, is attached. To the flask, 111.68 g (360 mmol) of bis-(3,4-dicarboxyphenyl)ether dianhydride (ODPA), 165.24 g (180 mmol) of diaminosiloxane compound BY16-853U (amino equivalent: 459) produced by Dow Corning Toray, 4.33 g (43 mmol) of γ-valerolactone, 6.83 g (86 mmol) of pyridine, 168 g of ethyl benzoate, 168 g of triglyme and 60 g of toluene are fed. After stirring the mixture at room temperature under a nitrogen atmosphere at 180 rpm for 30 minutes, the temperature was raised to 180° C. and the mixture was stirred for 1 hour. During the reaction, toluene-water azeotrope was removed.

After cooling the mixture to room temperature, 22.34 g (72 mmol) of bis-(3,4-dicarboxyphenyl)ether dianhydride (ODPA), 63.15 g (216 mmol) of 1,3-bis(3-aminophenoxy)benzene, 10.52 g (36 mmol) of 1,3-bis(4-aminophenoxy)benzene, 100 g of ethyl benzoate, 100 g of triglyme and 30 g of toluene were added, and the mixture was allowed to react at 180° C. for 5 hours with stirring at 180 rpm. By removing the refluxed material from the system, a polyimide solution having a concentration of 40% was obtained.

The molecular weight of the thus obtained polyimide was measured by gel permeation chromatography (produced by Tosoh). As a result, the number average molecular weight (Mn) was 36,000, weight average molecular weight (Mw) was 62,000, Z average molecular weight (Mz) was 65,000, and Mw/Mn=1.81, the molecular weights being in terms of polystyrene. The polyimide was poured into methanol and powdered, and subjected to thermal analysis. The glass transition temperature (Tg) was 153° C., and the temperature at which decomposition begins was 402.7° C.

### Synthesis Example 3

ODPA in an amount of 31.02 g (100 mmol), 93.00 g (100 mmol) of diaminosiloxane compound KF-8010 (amino equivalent: 415) produced by Shin-Etsu Chemical, 14.31 g (75 mmol) of 3,3′-dicarboxy-4,4′-diaminodiphenylmethane, 3.75 g (37.5 mmol) of γ-valerolactone, 5.93 g (50 mmol) of pyridine, 120 g of ethyl benzoate, 120 g of triglyme and 60 g of toluene are fed. After stirring the mixture at room temperature under a nitrogen atmosphere at 180 rpm for 30 minutes, the temperature was raised to 180° C. and the mixture was stirred for 1 hour. During the reaction, toluene-water azeotrope was removed.

After cooling the mixture to room temperature, 71.66 g (200 mmol) of 3,3′,4,4′-biphenylsulfonetetracarboxylic dianhydride, 61.58 g (150 mmol) of 2,2-bis[4-(4-aminophenoxy)phenyl]propane, 75 g of ethyl benzoate, 75 g of triglyme and 60 g of toluene were added, and the mixture was allowed to react at 180° C. for 5 hours with stirring at 180 rpm. By removing the refluxed material from the system, a polyimide solution having a concentration of 40% was obtained. The molecular weight, glass transition temperature and the temperature at which thermal decomposition begins were measured.

### Synthesis Example 4

A mixture of 43.43 g (140 mmol) of ODPA, 130.20 g (140 mmol) of diaminosiloxane compound KF-8010 (amino equivalent: 415) produced by Shin-Etsu Chemical, 40.93 g (140 mmol) of APB, 4.21 g (42 mmol) of γ-valerolactone, 6.64 g (84 mmol) of pyridine, 155 g of ethyl benzoate, 155 g of γBL and 60 g of toluene were stirred at room temperature under a nitrogen atmosphere at 180 rpm for 30 minutes, and the temperature was raised to 180° C., followed by stirring the mixture for 1 hour. During the reaction, toluene-water azeotrope was removed.

After cooling the mixture to room temperature, 90.22 g (280 mmol) of BTDA, 51.28 g (140 mmol) of 2,2-bis(3-amino-4-hydroxyphenyl)hexafluoropropane (Bis-AP-AF), 100 g of ethyl benzoate, 100 g of γBL and 40 g of toluene were added, and the mixture was allowed to react at 180° C. for 5 hours with stirring at 180 rpm. By removing the refluxed material from the system, a polyimide solution having a concentration of 40% was obtained. The molecular weight, glass transition temperature and the temperature at which thermal decomposition begins were measured.

### Synthesis Example 5

The reaction of the first step was carried out as in Synthesis Example 1 using 93.07 g (300 mmol) of ODPA, 139.50 g (150 mmol) of diaminosiloxane compound KF-8010 (amino equivalent: 415) produced by Shin-Etsu Chemical, 60 g of toluene, 6.01 g (60 mmol) of γ-valerolactone, 9.49 g (120 mmol) of pyridine, 126 g of γBL and 126 g of ethyl benzoate.

The mixture was then cooled to room temperature, and a polyimide solution having a concentration of 40% was obtained as in Synthesis Example 1 using 23.27 g (75 mmol) of ODPA, 21.93 g (75 mmol) of 1,3-bis(4-aminophenoxy)benzene, 37.25 g (150 mmol) of 4,4′-diaminodiphenylsulfone, 40 g of toluene, 100 g of ethyl benzoate and 100 g of γBL.

The molecular weight, glass transition temperature and the temperature at which thermal decomposition begins of the thus obtained polyimide were measured. The results are shown in Table 1.

The curling property¹⁾, line-to-line insulation properties²⁾, solder heat resistance³⁾, fire retardancy⁴⁾ and adhesiveness with substrates⁵⁾ which are basic properties of polyimide varnish synthesized in Synthesis Examples 1 to 5 are shown in Table 2.

1) The radius of curvature of the curl of a wiring member (5×5 cm) coated with a protective film.
2) The value measured by JIS-05016
3) A wiring member (5×5 cm) coated with a protective film was observed to examine bulging and the like.
4) Flammability test according to UL Safety Standard. After cutting out a sample, the sample was treated at 25° C., 50% RH for 24 hours, and then immersed in a solder at 260° C., and subjected to the flammability test.
5) Adhesive strength (180° peel) to polyimide film Capton (EN) and roll annealed copper foil BHY22BT (produced by Nikko Materials).

TABLE 1

| | Synthesis Example | | | | |
|---|---|---|---|---|---|
| | 1 | 2 | 3 | 4 | 5 |
| Polyimide solid | 45 | 40 | 40 | 40 | 40 |
| concentration (%) | | | | | |
| Weight average | 38000 | 60000 | 60000 | 57000 | 55000 |
| molecular weight | | | | | |
| Grass transition | 112 | 153 | 171 | 113 | 183 |
| temperature/° C. | | | | | |
| Temperature at which | 410 | 403 | 428 | 437 | 440 |
| thermal decomposition | | | | | |
| begins/° C. | | | | | |
| Modulus of elasticity | 91 | 818 | 650 | 780 | 545 |
| (N/mm²) | | | | | |
| Tensile strength (N/mm²) | 28 | 31 | 30 | 35 | 40 |
| Extension rate (%) | 500 | 65 | 55 | 100 | 114 |

TABLE 2

| | | Line-to-line | | | Adhesion | | Adhesion | |
|---|---|---|---|---|---|---|---|---|
| | Curling | Insulation | Solder Heat | | (N/cm initial⁵⁾) | | (N/cm) 150° C., 10 days | |
| Synthesis | Property¹⁾ | Resistance²⁾ | Resistance³⁾ | Fire | On copper | | On copper | |
| Example | mm | Ω | ° C. | Retardancy⁴⁾ | foil | On PI | foil | On PI |
| 1 | 1 | 1.0 × 10¹⁴ | 260° C. | VTM3 | 18 | 20 | 14 | 18 |
| | | | 10 seconds | | | | | |
| 2 | 2 | 3.0 × 10¹⁵ | 260° C. | VTM2 | 5 | 6 | 4 | 5 |
| | | | 30 seconds | | | | | |
| 3 | 1 | 3.0 × 10¹⁵ | 260° C. | VTM2 | 8 | 6 | 6 | 5 |
| | | | 30 seconds | | | | | |
| 4 | 0 | 2.0 × 10¹⁴ | 260° C. | VTM2 | 12 | 8 | 10 | 6 |
| | | | 60 seconds | | | | | |
| 5 | 0 | 1.0 × 10¹⁴ | 280° C. | VTM1 | 20 | 12 | 18 | 10 |
| | | | 60 seconds | | | | | |

### Examples 1-11

To the polyimide varnish synthesized in Synthesis Example 1, phthalocyanine which is an organic pigment and the necessary filler(s) were added in the amounts shown in Table 3, and the mixture was sufficiently mixed with NR-120A ceramic 3-roll mill produced by Noritake to obtain a polyimide ink for printing according to the present invention.

TABLE 3

| | | | Filler | | Phthalocyanine | |
|---|---|---|---|---|---|---|
| | Varnish Synthesis | Polyimide Solid | | Added Amount | | Added Amount |
| Example | Example | Concentration (%) | Type | (parts) | Type | (parts) |
| 1 | 1 | 45 | | — | 4966 | 5 |
| 2 | 1 | 45 | R972 | 10 | 4966 | 2 |
| 3 | 2 | 40 | RX200 | 5 | 4966 | 2 |
| 4 | 2 | 40 | E200A | 5 | 4966 | 2 |
| 5 | 3 | 40 | R972 | 5 | 4966 | 2 |
| | | | SOE1 | 10 | | |
| 6 | 3 | 40 | R972 | 10 | 4966 | 2 |
| | | | E200A | 5 | | |
| 7 | 4 | 40 | E200A | 3 | 4966 | — |
| | | | RX200 | 5 | | |
| 8 | 4 | 40 | R972 | 2 | 4966 | 2 |
| | | | Mg(OH)₂ | 5 | | |
| 9 | 5 | 45 | R972 | 5 | 4966 | 2 |
| 10 | 5 | 45 | Mg(OH)₂ | 5 | 4966 | 2 |
| 11 | 5 | 45 | Al(OH)₃ | 5 | 4966 | 2 |
| 12 | 1 | 45 | SPE-100 | 20 | 4966 | 2 |
| 13 | 2 | 40 | SPE-100 | 5 | 4966 | 2 |
| 14 | 2 | 40 | MC-860 | 5 | 4966 | 2 |

Note 1)
The added amounts of Phthalocyanine Blue powder and the fillers were the added amount (parts by weight) to 100 parts by weight of the polyimide resin solid.
Note 2)
Fillers
R972: Aerosil (produced by Nippon Aerosil): average primary particle size 0.01 to 0.02 μm
RX200: Aerosil (produced by Nippon Aerosil): average primary particle size 0.016 μm
E200A: Amorphous silica (produced by Nippon Silica): average primary particle size 0.3 μm
SOE1: Spherical silica (produced by Admatechs): average primary particle size 0.2 μm
Mg(OH)₂: magnesium hydroxide (produced by TMG Corporation): average secondary particle size 0.9 μm
Al(OH)₃: aluminum hydroxide (produced by Kawai Lime Industrial Co., Ltd): average secondary particle size 2.0 μm
Phthalocyanine Blue 4966 (produced by Dai-Nippon Seika Kogyo): average primary particle size 1 to 5 μm
SPE-100: phosphazene-based flame retardant (produced by Otsuka Chemical): average primary particle size 1 to 5 μm
MC-860: melamine cyanurate (produced by Nissan Chemical Industries): average primary particle size 1 to 5 μm

### Evaluation Example 1

The compositions of Examples 2 to 9 were evaluated for their fire retardancy. The results are shown in Table 4

TABLE 4

| Example | (UL-94VTM) Results of Fire Retardancy Test |
|---|---|
| 1 | UL-94VTM-2 |
| 2 | UL-94VTM-1 |
| 3 | UL-94VTM-2 |
| 4 | UL-94VTM-1 |
| 5 | UL-94VTM-1 |
| 6 | UL-94VTM-0 |
| 7 | UL-94VTM-1 |
| 8 | UL-94VTM-0 |
| 9 | UL-94VTM-0 |
| 10 | UL-94VTM-0 |
| 11 | UL-94VTM-0 |
| 12 | UL-94VTM-0 |
| 13 | UL-94VTM-0 |
| 14 | UL-94VTM-0 |

### Evaluation Example 2

### Evaluation of Printing Property

Printing was performed using a printing mask for tests produced by PI R&D and using MT-550TVC screen printing machine produced by Microtech. The printing plate used in the evaluation was the printing screen for tests (made of 350-mesh stainless steel, emulsion thickness 20 μm), which is a metal mask plate (made of 350-mesh stainless steel, plating thickness: 20 μm), and has a frame size of 200 mm×250 mm. Printing was performed under the printing conditions wherein the squeegee speed was 50 to 100 mm/min, the gap (clearance) was 1.5 mm to 2.0 mm, and the squeegee printing pressure was 0.1 to 0.2 MPa, and characteristics of the following items were evaluated:

As for the pattern shape of the polyamide protective film, using a flexible circuit wiring board prepared by PI R&D, the printing property on the circuit wiring board and the printing property in printing through hole patterns were examined. More specifically, the ink was printed on the entire surface of a wiring board having line/space patterns of copper wiring of: 30/30 μm, 50/50 μm, 100/100 μm and 200/200 μm, and whether the ink was embedded between spaces or not was examined. Further, as for the printing property of through hole patterns, evaluation was performed using those having circular pattern shape (diameters of 100 μm and 200 μm, respectively) and those having square pattern shape (lengths of sides of 100 μm and 200 μm, respectively), wherein the patterns were arranged at a pitch of 250 μm in 10 lines and 10 columns. Twenty shots of printing were carried out continuously. Since the printing was stable from the first shot to the 20th shot, the sample of the 20 shots was evaluated. After carrying out the continuous 20 shots of printing, leveling was performed at room temperature for 5 to 10 minutes, and each board was heated in ovens at 90° C., 180° C. and 220° C. respectively for 30 minutes each to remove the organic solvent component. Using the resultant samples, the embedding in the circuit and the shapes of patterns were evaluated visually and with a light microscope, respectively. Evaluations were performed on deficiency of insufficient embedding in the circuit, “blur and run deficiency” (the deficiency wherein the paste was spread in the widthwise direction of the pattern and bridged the adjacent patterns), “void or chip”, and “rolling property” (deficiency of the state of rolling of the paste when the paste was flown in the form of substantially cylindrical shape in the front side of the direction of movement of the squeegee on the screen when the squeegee moved). The results are shown in Table 5.

TABLE 5

| | Number of Defficiencies in Embedding in Circuit Wiring and Pattern Shape (N = 10) | | | | | | Evaluation of |
|---|---|---|---|---|---|---|---|
| | Embedding | Blur or Run | Thin Spotting | Void or | Rolling | | Shape |
| Example | Difficiency | Difficiency | Difficiency | Chipping | Property | Total | good |
| Example 1 | 0 | 2 | 0 | 0 | good | 2 | good |
| Example 2 | 0 | 0 | 2 | 0 | good | 2 | good |
| Example 3 | 0 | 0 | 1 | 0 | good | 1 | good |
| Example 4 | 0 | 0 | 1 | 0 | good | 1 | good |
| Example 5 | 0 | 0 | 1 | 0 | good | 1 | good |
| Example 6 | 0 | 0 | 0 | 0 | very good | 0 | good |
| Example 7 | 2 | 0 | 2 | 3 | moderate | 7 | good |
| Example 8 | 0 | 0 | 0 | 0 | very good | 0 | good |
| Example 9 | 0 | 0 | 0 | 0 | very good | 0 | good |
| Example 10 | 0 | 0 | 0 | 0 | very good | 0 | good |
| Example 11 | 0 | 0 | 0 | 0 | very good | 0 | good |
| Example 12 | 0 | 0 | 0 | 0 | very good | 0 | good |
| Example 13 | 0 | 0 | 0 | 0 | very good | 0 | good |
| Example 14 | 0 | 0 | 0 | 0 | very good | 0 | good |

Each of the above-described samples was subjected to evaluation of bending (1R, outer bending) was performed. As a result, in any of the samples, change in resistance of the copper wiring was not observed, and a crack at the bent site was not observed.

### (Continuous Printing Property)

This evaluation is for evaluating whether the desired pattern can be printed continuously 100 times without substantially changing the pattern dimension or not.

The pattern was continuously printed, and the pattern printed at the 10th shot was sampled, and thereafter the printed patterns were sampled at 10-shot intervals up to the one printed at the 100th shot. The pattern shape of the sampled patterns was observed, after being dried, visually and with a light microscope in the same manner as in the evaluation of the pattern. The results are shown in Table 6. In the table, the mark ◯ in the item of continuous shot means that the pattern shape was good, and the mark Δ means that the pattern shape was slightly deformed. In cases where the pattern shape was changed very bad, the printing was stopped.

TABLE 6

| | Number of Continuous Shots | | | | | | | | | |
|---|---|---|---|---|---|---|---|---|---|---|
| | 10 | 20 | 30 | 40 | 50 | 60 | 70 | 80 | 90 | 100 |
| Example 1 | ◯ | ◯ | ◯ | ◯ | ◯ | ◯ | ◯ | ◯ | Δ | Δ |
| Example 2 | ◯ | ◯ | ◯ | ◯ | ◯ | ◯ | ◯ | ◯ | ◯ | Δ |
| Example 3 | ◯ | ◯ | ◯ | ◯ | ◯ | ◯ | ◯ | ◯ | ◯ | Δ |
| Example 4 | ◯ | ◯ | ◯ | ◯ | ◯ | ◯ | ◯ | ◯ | ◯ | Δ |
| Example 5 | ◯ | ◯ | ◯ | ◯ | ◯ | ◯ | ◯ | ◯ | ◯ | Δ |
| Example 6 | ◯ | ◯ | ◯ | ◯ | ◯ | ◯ | ◯ | ◯ | ◯ | ◯ |
| Example 7 | ◯ | ◯ | ◯ | ◯ | ◯ | ◯ | ◯ | ◯ | Δ | Δ |
| Example 8 | ◯ | ◯ | ◯ | ◯ | ◯ | ◯ | ◯ | ◯ | ◯ | ◯ |
| Example 9 | ◯ | ◯ | ◯ | ◯ | ◯ | ◯ | ◯ | ◯ | ◯ | ◯ |
| Example 10 | ◯ | ◯ | ◯ | ◯ | ◯ | ◯ | ◯ | ◯ | ◯ | ◯ |
| Example 11 | ◯ | ◯ | ◯ | ◯ | ◯ | ◯ | ◯ | ◯ | ◯ | ◯ |
| Example 12 | ◯ | ◯ | ◯ | ◯ | ◯ | ◯ | ◯ | ◯ | ◯ | ◯ |
| Example 13 | ◯ | ◯ | ◯ | ◯ | ◯ | ◯ | ◯ | ◯ | ◯ | ◯ |
| Example 14 | ◯ | ◯ | ◯ | ◯ | ◯ | ◯ | ◯ | ◯ | ◯ | ◯ |

As seen from the results shown in Tables 5 and 6, the polyimide ink for printing according to the present invention showed excellent pattern shape and continuous printing property. Further, with the type of ink of which viscosity was decreased to less than that of the ink for printing, the required portions were able to be coated simply by precision dispensing method.

### INDUSTRIAL AVAILABILITY

The polyimide ink composition for printing according to the present invention are suitable as an ink for forming films in electronic parts, that is, for forming protective layers of flexible wiring boards and circuit boards used in operator panels and the like of various electronic devices in the field of electronics, for forming insulating layers of laminated boards, and for protection, insulation or adhesion of silicon wafers, silicon chips, peripheral members of semiconductor devices, boards for mounting semiconductor chips, radiator plates, lead pins, and semiconductors per se, used in semiconductor devices.

Especially, formation of images of polyimide films used as surface protection films and interlayer insulating films, that is, used as conventional industrial coating materials of electronic parts, such as surface-coating materials of flexible printing boards, inner layer-coating materials of multilayer rigid boards, alignment layers of liquid crystals, coating materials of IC and LSI, have been carried out by photoetching methods using photoresists. However, since the techniques for photoprinting using photosensitive polyimides were greatly advanced in recent years, the image-forming steps have been more simplified and uses of polyimides in the field of electronics have been more and more spread. However, irrespective of whether the polyimide is photosensitive or not, coating of most of the conventional polyimides were performed by the spinner method having a low coating efficiency, so that the promotion of coating efficiency and further simplification of the image-forming steps are demanded. By using the ink composition according to the present invention, since images can be directly formed on the substrates using a screen or metal mask without performing the steps of exposure, development and etching, images can be formed more simply than by the photoetching method or photoprinting method.

1. A polyimide ink composition for printing, comprising a mixed solvent containing a benzoic acid ester solvent and a glyme solvent, and a polyimide soluble in said mixed solvent; wherein said polyimide is obtained by polycondensing a polyimide oligomer with a tetracarboxylic dianhydride component(s) and/or a diamine component(s) having no siloxane bond in molecular skeleton thereof, said polyimide oligomer being prepared by polycondensing a tetracarboxylic dianhydride component(s) and a diamine component(s) having siloxane bonds in molecular skeleton thereof in the presence of a base catalyst(s), or a mixed catalyst including a lactone(s) and/or an acidic compound(s) and a base(s); the content of said diamine component(s) having siloxane bonds based on the total diamine components being 15 to 85% by weight.

2. The polyimide ink composition for printing, according to claim 1, wherein said diamine component(s) having no siloxane bond is an aromatic diamine(s) and/or aromatic diamine carboxylic acid(s).

3. The polyimide ink composition for printing, according to claim 1, wherein said diamine(s) having siloxane bonds in the molecular skeleton thereof has(have) the structure represented by the following General Formula (I): 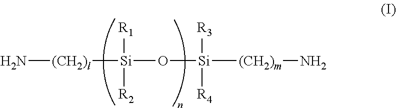
(wherein in Formula (I), R₁, R₂, R₃ and R₄ each independently represents alkyl, cycloalkyl, phenyl, or phenyl substituted with 1 to 3 alkyl or alkoxyl groups; l and m each independently represents an integer of 1 to 3; and n represents an integer of 3 to 30).

4. The polyimide ink composition for printing, according to claim 1, wherein said polyimide has a weight average molecular weight (molecular weight in terms of styrene) of 30,000 to 200,000.

5. The polyimide ink composition for printing, according to any one of claims 1 to 3, wherein said composition has a polyimide content of 30 to 50% by weight.

6. The polyimide ink composition for printing, according to any one of claims 1 to 3, further comprising a filler in an amount of 5 to 20 parts by weight with respect to 95 to 80 parts by weight of said polyimide.

7. The polyimide ink composition for printing, according to claim 6, wherein said filler is an insulating inorganic filler, resin-coated inorganic filler and/or resin filler.

8. The polyimide ink composition for printing, according to claim 6, wherein said filler is particles having an average particle size of 0.001 μm to 10 μm.

9. The polyimide ink composition for printing, according to claim 6, wherein said filler is at least one selected from the group consisting of silica particles, spherical or amorphous silica, hydrated metal compounds, aluminum oxide, titanium dioxide, phosphorus compounds, epoxy resins, melamine polyphosphate, melem, melamine cyanurate, maleimide resins, polyurethane resins, polyimides, polyamides and triazine.

10. The polyimide ink composition for printing, according to any one of claims 1 to 3, further comprising as a coloring agent a halogen-free phthalocyanine which is an organic pigment in an amount of 2 to 10% by weight based on the amount of said polyimide.

11. A method for forming a polyimide ink film, said method comprising directly applying or patterning said polyimide ink composition according to any one of claims 1 to 3 by a printing method or precision dispensing method in one operation.

12. An electric circuit board having an insulating protective film, said electric circuit hoard being produced by a process comprising: forming, by the method of claim 11, a polyimide ink film(s) as a protective insulating layer(s) on a wiring(s) on a flexible circuit board; and heat-treating the resulting structure.

13. The electric circuit board according to claim 12, wherein said protective insulating layer(s) has(have) a modulus of elasticity of not more than 1000 N/mm².
